(19) United States
(12) Patent Application Publication
(10) Pub. No.: US 2026/0101594 A1
(43) Pub. Date: Apr. 9, 2026

(54) GaN-BASED RADIATION DETECTOR

(71) Applicant: BTOZ INC., Gyeongju-si, Gyeongsangbuk-do (KR)

(72) Inventor: Hyun Jae LEE, Hongseong-gun (KR)

(73) Assignee: BTOZ INC., Gyeongju-si, Gyeongsangbuk-do (KR)

(21) Appl. No.: 19/114,193

(22) PCT Filed: Jul. 3, 2024
(86) PCT No.: PCT/KR2024/009376

§ 371 Date: Mar. 21, 2025

(30) Foreign Application Priority Data
Aug. 1, 2023 (KR) 10-2023-0100505

(51) Int. Cl. H10F 30/295; H10F 77/124; H10F 77/14

(52) U.S. Cl. CPC H10F 30/295; H10F 77/1243; H10F 77/1246; H10F 77/147

(57) ABSTRACT

The present invention relates to a GaN-based radiation detector capable of detecting radiation such as X-rays. The GaN-based radiation detector includes: an n-doped GaN layer having an electron mobility of 700 cm²/(V·s) or more and a thickness of 300 μm or more and doped with an n-type doping concentration of 3×10¹⁶/cm³ or less; a p-doped GaN layer formed on one surface of the n-doped GaN layer and having a thickness of 3 μm or less and doped with a p-type doping concentration of 5×10¹⁸/cm³ or more; a first metal contact formed on the other surface of the n-doped GaN layer; and a second metal contact formed on one surface of the p-doped GaN layer.

### TECHNICAL FIELD

The present invention relates to GaN(gallium nitride)-based radiation detector capable of detecting radiation such as X-rays.

### BACKGROUND ART

Recently, most direct transition type radiation detectors are manufactured using α-Se (amorphous selenium) or CdTe (cadmium telluride) materials. As is known, a-Se is very expensive to manufacture, and cadmium is a heavy metal that is very dangerous to the human body. In order to solve these problems, the development of a direct-type semiconductor radiation detector is urgent.

Materials such as GaAs (gallium arsenide), SiC (silicon carbide), Ga₂O₃ (gallium oxide), and GaN (gallium nitride) are being discussed as suitable materials for direct transition radiation detectors. However, considering durability under radiation, efficiency as a direct transition semiconductor, and process convenience, GaN is known to be the best alternative.

Recently, in the research field of GaN-based radiation detectors, many results have been reported that prove their advantages as radiation detectors, and in particular, they have been reported to be able to appropriately detect ultraviolet rays, neutrons, X-rays, and the like.

Since most existing GaN-based radiation detectors are formed by epitaxial growth using a MOCVD (metal organic chemical vapor deposition) process on sapphire (Al₂O₃) or silicon carbide (SIC) substrates, the growth thickness is thin, less than 30 μm and therefore, the drift layer, which is the region where electrons and holes are generated by the incident radiation, is thin, and since this thin drift layer is utilized, it has the disadvantages of reduced efficiency and complicated structure. This is due to limitations in the growth method, and in addition, since the drift layer must have very high electron mobility, the impurity or doping concentration must be basically low. In addition, the doping concentration increases due to defects caused by the difference in lattice constant due to growth on different substrates and the incorporation of impurities during crystal growth, which causes a decrease in the efficiency and response speed of the detector. A method for manufacturing a GaN-based radiation detector for solving these problems and having improved efficiency and improved response speed is required.

The matters described in the technical background of this invention have been written to increase understanding of the background of the invention and may include matters that are not prior art already known in the field to which this technology belongs.
Prior art document: US Patent Publication No. U.S. pat. No. 9,402,548 (2016, Aug. 2.)

### DETAILED DESCRIPTION OF THE INVENTION

### Technical Problem

The problem to be solved by the present invention is to provide a GaN-based radiation detector capable of improving efficiency, improving response speed, and implementing a simple structure.

The technical problems to be achieved by the present invention are not limited to the technical problems mentioned above, and other technical problems not mentioned can be understood by a person having ordinary skill in the technical field to which the present invention belongs from the description below.

### Technical Solutions

### Claim 1

A GaN-based radiation detector according to an embodiment of the present invention includes: an n-doped GaN layer having an electron mobility of 700 cm²/(V·s) or more and a thickness of 300 μm or more and doped with an n-type doping concentration of 3×10¹⁶/cm³ or less; a p-doped GaN layer formed on one surface of the n-doped GaN layer and having a thickness of 3 μm or less and doped with a p-type doping concentration of 5×10¹⁸/cm³ or more as a p-type; a first metal contact formed on the other surface of the n-doped GaN layer; and a second metal contact formed on one surface of the p-doped GaN layer.

A GaN-based radiation detector according to another embodiment of the present invention includes: an n-doped GaN layer having an electron mobility of 700 cm²/(V·s) or more and a thickness of 300 μm or more and doped with an n-type doping concentration of 3×10¹⁶/cm³ or less; a first p-doped GaN layer formed on one surface of the n-doped GaN layer and doped with a first p-doping concentration of 5×10¹⁸/cm³ or more; a second p-doped GaN layer formed on one surface of the first p-doped GaN layer and doped with a second doping concentration of 5×10¹⁹/cm³ or more that is greater than the first p-doping concentration; a first metal contact formed on the other surface of the n-doped GaN layer; and a second metal contact formed on one surface of the second p-doped GaN layer.

A GaN-based radiation detector according to another embodiment of the present invention includes: an n-doped GaN layer having an electron mobility of 700 cm²/(V·s) or more and a thickness of 300 μm or more and doped with an n-type doping concentration of 3×10¹⁶/cm³ or less; a plurality of p-doped GaN layers formed on one surface of the n-doped GaN layer and sequentially doped with different p-doping concentrations in a range of 5×10¹⁸/cm³ to 5×10²⁰/cm³ and having a thickness of 1 μm or less; a first metal contact formed on the other surface of the n-doped GaN layer; and a second metal contact formed on one surface of the plurality of p-doped GaN layers.

A part of the p-doped GaN layer may be able to be removed.

At least a portion of one surface of the n-doped GaN layer may have a rough structure.

A defect concentration of the n-doped GaN layer may be 5×10⁶/cm² or less.

A GaN-based radiation detector according to another embodiment of the present invention includes: a first n-doped GaN layer having an electron mobility of 700 cm2/(V·s) or more and a thickness of 300 μm or more and doped with an n-type doping concentration of 3×10¹⁶/cm³ or less; a second n-doped GaN layer formed on one surface of the first n-doped GaN layer and having a thickness of 5 μm or less and doped with an n-type doping concentration of 5×10¹⁷/cm³ or more; a first metal contact formed on the other surface of the first n-doped GaN layer; and a second metal contact formed on one surface of the second n-doped GaN layer.

A part of the second n-doped GaN layer may be able to be removed.

At least a portion of a nitrogen surface of the n-doped GaN layer may be formed to have a rough structure.

### Effect of the Invention

According to the present invention, a GaN-based radiation detector having improved efficiency and response speed can be implemented.

In addition, various effects that can be obtained or expected due to the embodiments of the present invention are directly or implicitly disclosed in the detailed description of the embodiments of the present invention.

### BRIEF DESCRIPTION OF THE DRAWINGS

The drawings attached below are intended to help understanding of the present invention and provide embodiments of the present invention together with a detailed description. However, the technical features of the present invention are not limited to specific drawings, and the features disclosed in each drawing may be combined with each other to form new embodiments. The embodiments of the present specification may be better understood by referring to the following description in conjunction with the attached drawings in which similar reference numerals designate identical or functionally similar elements.

FIG. 1 is a schematic cross-sectional view of a GaN-based radiation detector according to an embodiment of the present invention.

FIG. 2 shows a modified example of a GaN-based radiation detector according to the embodiment of FIG. 1.

FIG. 3 shows another modified example of a GaN-based radiation detector according to the embodiment of FIG. 1.

FIG. 4 shows a schematic cross-sectional view of a GaN-based radiation detector according to another embodiment of the present invention.

FIG. 5 shows a modified example of a GaN-based radiation detector according to the embodiment of FIG. 4.

FIG. 6 shows another modified example of a GaN-based radiation detector according to the embodiment of FIG. 4.

FIG. 7 shows a schematic cross-sectional view of a GaN-based radiation detector according to another embodiment of the present invention.

FIG. 8 shows a modified example of a GaN-based radiation detector according to the embodiment of FIG. 7.

FIG. 9 shows another modified example of a GaN-based radiation detector according to the embodiment of FIG. 7.

FIG. 10 shows another modified example of a GaN-based radiation detector according to the embodiment of FIG. 7

FIG. 11 shows another modified example of a GaN-based radiation detector according to the embodiment of FIG. 7.

It should be understood that the drawings referenced above are not necessarily drawn to scale and are intended to provide a simplified representation of various features that illustrate the basic principles of the present invention. For example, specific design features of the present invention, including specific dimensions, orientations, positions, and shapes, will be determined in part by the particular intended application and usage environment.

### EMBODIMENTS FOR CARRYING OUT THE INVENTION

Hereinafter, with reference to the attached drawings, embodiments of the present invention will be described in detail so that those skilled in the art can easily implement the present invention. However, the present invention may be implemented in various different forms and is not limited to the embodiments described.

The terminology used herein is for the purpose of describing specific embodiments only and is not intended to limit the present invention. As used herein, the singular forms “a,” “an,” and “the” are intended to include the plural forms as well, unless the context clearly indicates otherwise. It should also be understood that the terms “comprises” and/or “comprising” as used herein indicate the presence of stated features, integers, steps, operations, elements, and/or components, but do not preclude the presence or addition of one or more other features, integers, steps, operations, components, and/or groups thereof. As used herein, the term “and/or” includes any one or all combinations of one or more of the associated listed items. The term “coupled” indicates a physical relationship between two components in which the components are directly connected to each other or indirectly connected through one or more intermediary components.

In describing a component of the present invention, when it is described that a component is “connected,” “coupled,” or “adjoined” to another component, it should be understood that the component may be directly connected, coupled, or connected to the other component, but that another component may also be “connected,” “coupled,” or “adjoined” between each component.

Currently, the only technology that can stack GaN layes thicker than 100 μm is HVPE (hydride vapor phase epitaxy), but HVPE technology has been limited in its use due to the disadvantages of high doping concentration and low electron mobility caused by the mixing of impurities during growth. In particular, although, when growing a thick GaN drift layer using the HVPE method, there is a method to lower the concentration of n-type impurities by artificially mixing p-type impurities such as carbon (C) or iron (Fe) to prevent the increase in n-type impurity concentration due to the mixing of silicon (Si) or oxygen (O) impurities, this method causes a decrease in efficiency and response speed due to the decrease in electron mobility. Therefore, the n-type doping concentration must be reduced to 3×10¹⁶/cm³ or less through a technology that minimizes silicon or oxygen impurities during GaN growth using the HVPE method in order to improve the electron mobility to 700 Cm²/(V·s) or more.

Recently, research on technologies for reducing silicon and oxygen impurities in HVPE growth methods has been actively conducted. In particular, it has been reported that these impurities can be controlled by replacing the quartz tube, which is the reaction tube material of the HVPE device, with a different material or by changing the source gas for growing GaN.

If the GaN substrate itself, which has a thickness of 300 μm or more and has an n-type doping concentration of 3×10¹⁶/cm³ or less and an electron mobility of 700 Cm²/(V·s) or more through impurity reduction technology in GaN growth by HVPE, is used as a drift layer, a greater effect can be obtained. Increasing the thickness of the drift layer can promote radiation absorption and form more current, and can also increase the response speed through higher driving voltage. In addition, it has the advantage of reducing leakage current through defect reduction, thereby reducing signal noise and improving reliability. Furthermore, since more electron and hole pairs can be generated in a thicker drift layer, the device structure can be simplified.

In particular, since a thick GaN substrate with low defects, low doping concentration, and high electron mobility can be used, a thick drift layer and a defect-reducing effect can be accordingly obtained, so that even if either the (p) GaN or the (n+) layer is removed, the device can be manufactured as a simpler device with improved characteristics, and thus a reduction in manufacturing cost can be expected. In particular, a GaN-based radiation detector manufactured with this structure has a higher breakdown voltage than a conventional detector. Since the breakdown voltage of a device is determined by the doping concentration, defects, and thickness of the drift layer, a device with a higher breakdown voltage can be driven at a higher voltage, which facilitates electron transport at the Schottky contact that occurs between metal-semiconductor junctions.

In the conventional method, an (n+) GaN layer doped with 5×10¹⁷/cm³ or more on a sapphire or silicon carbide substrate must be used, but if a GaN substrate with a low impurity concentration is used, it is sufficient to use only the Schottky contact while removing the (n+) GaN layer. In addition, the (p+) GaN layer doped with 5×10¹⁸/cm³ or more can also be removed. In other words, normal operation can be achieved with only one of the (n+) GaN layer and the (p+) GaN layer. This is due to the advantage of Schottky contact being possible because operation at high voltage is possible. In addition, a surface roughness structure can also be inserted to help radiation absorption.

The GaN substrate used as a drift layer to manufacture devices for GaN-based radiation detectors reduces the silicon or oxygen impurities mixed in during manufacturing, thereby reducing the n-type doping concentration and increasing electron mobility. At this time, preferably, the GaN substrate has an n-type doping concentration of 3×10¹⁶/cm³ or less, an electron mobility of 700 Cm²/(V·s) or more, and a thickness of 300 μm or more. On the substrate prepared in this way, one layer of (p+) GaN or (n+) GaN is grown through MOCVD. A portion of the grown MOCVD epilayer is etched and an electrode is formed. In addition, a portion of one side of the (n−) GaN layer may be etched with a wet-etching method to create a rough structure to increase the absorption rate of incident radiation.

Hereinafter, embodiments of the present invention will be described with reference to the drawings.

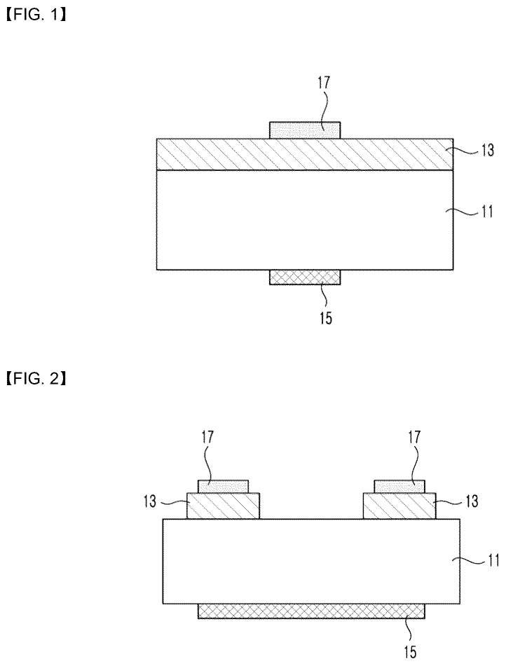

Referring to FIG. 1, a GaN-based radiation detector 10 includes an n-type doped n-doped GaN layer 11, and the n-doped GaN layer 11 corresponds to a GaN substrate to be used as a drift layer. To improve the response speed and reliability, the n-doped GaN layer 11 is formed by doping the GaN layer with an n-type doping concentration of 3×10¹⁶/cm³ or less and has an electron mobility of 700 cm²/(V·s) or more and a thickness of 300 um or more. Furthermore, the defect concentration of the n-doped GaN layer 11 can be 5×10⁶/cm² or less.

A p-doped GaN layer 13 is formed on the upper surface of the n-doped GaN layer 11, and for example, the p-doped GaN layer 13 may be formed by a method such as MOCVD. The p-doped GaN layer 13 is formed by doping the GaN layer with a p-type doping concentration of 5×10¹⁸/cm³ or more and has a thickness of 3 μm or less.

Metal contacts 15 and 17 that function as electrodes are formed on the lower surface of the n-doped GaN layer 11 and the upper surface of the p-doped GaN layer 13, respectively. The metal contact 15 formed on the lower surface of the n-doped GaN layer 11 functions as a cathode, and the metal junction 17 formed on the upper surface of the p-doped GaN layer 13 functions as an anode. Although not shown in the drawing, an electric signal generated by detecting radiation, for example, X-rays, can be generated through an electric circuit electrically connected to the cathode 15 and the anode 17.

The n-type doping described above can be achieved by n-type doping using silicon (Si) as a dopant, and silane (SiH₄) can be used as a dopant source. Also, the p-type doping can be achieved by p-type doping using magnesium Mg as a dopant, and biscyclopentadienyl-magnesium can be used as a dopant source.

FIGS. 2 and 3 illustrate modified examples of the GaN-based radiation detector of FIG. 1. The same parts are given the same reference numerals and repeated descriptions are omitted. Referring to FIGS. 2 and 3, a part of the p-doped GaN layer 13, for example, the central part thereof, can be removed. Partial removal of the p-doped GaN layer 13 can be accomplished through a process such as etching. In this regard, the anode 17 can be formed to have a ring shape in the remaining portion after partial removal, and the cathode 15 can be formed with a larger area to cover the entire area occupied by the anode 17.

Meanwhile, referring to FIG. 3, a rough structure 19 can be formed on a part of the n-doped GaN layer 1, for example, on at least a part of the bottom surface. In this regard, the bottom surface of the n-doped GaN layer 11 can be a nitrogen surface where nitrogen atoms are mainly exposed. At this time, the cathode 15 can be formed on the rough structure 19. The absorption of the radiation to be detected, for example, X-rays, can be increased by the rough structure 19. For example, the rough structure 19 can be formed by a process such as etching.

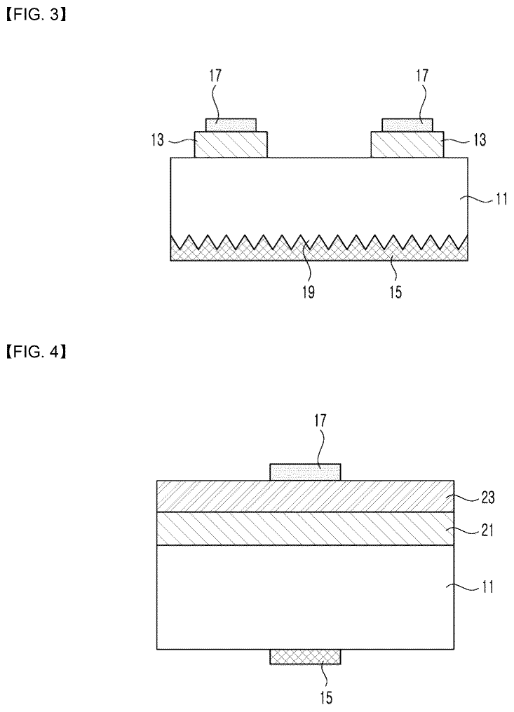

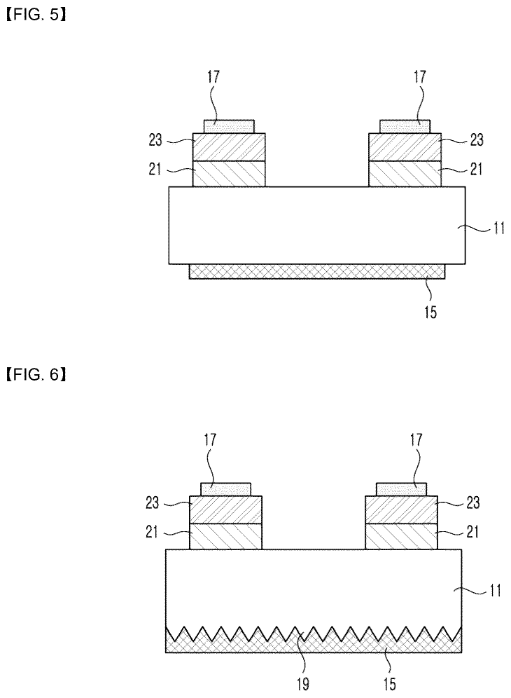

Referring to FIG. 4, a first p-doped GaN layer 21 and a second p-doped GaN layer 23, which are p-doped with different p-doping concentrations, are sequentially formed on an n-doped GaN layer 11 which is the same GaN substrate as the embodiment of FIG. 1. The first and second p-doped GaN layers 21 and 23 can be formed by doping the GaN layer with a p-type. The first p-doped GaN layer 21 is formed on the upper surface of the n-doped GaN layer 11 and can be doped with a first p-doping concentration of 5×10¹⁸/cm³ or more as a p-type, and the second p-doped GaN layer 23 is formed on the upper surface of the first p-doped GaN layer 21 and can be doped with a second doping concentration of 5×10¹⁹/cm³ or more as a p-type, which is greater than the first p-doping concentration.

Metal contacts 15 and 17 acting as electrodes may be formed on the lower surface of the n-doped GaN layer 11 and the upper surface of the second p-doped GaN layer 23, respectively, thereby forming a cathode and an anode.

According to another embodiment of the present invention, a plurality of p-doped GaN layers having a thickness of 1 um or less and continuously doped with different p-doping concentrations ranging from 5×10¹⁸/cm³ to 5×10²⁰/cm³ as p-type on the n-doped GaN layer 11 described above may be included. At this time, the p-doped GaN layers may be doped with p-type at a better p-doping concentration as they go up. For example, when two p-doped GaN layers are formed as shown in FIG. 4, the lower p-doped GaN layer is doped with a p-doping concentration ranging from 5×10¹⁸/cm³ to 5×10²⁰/cm³, and the upper p-doped GaN layer is doped with a p-doping concentration ranging from 5×10¹⁹/cm³ to 5×10²⁰/cm³, which is higher than the lower p-doped GaN layer. Furthermore, in another embodiment, three or more p-doped GaN layers may be formed in sequence.

FIGS. 5 and 6 illustrate modified examples of the GaN-based radiation detector of FIG. 4. The same reference numerals are used for the same parts, and repeated descriptions are omitted. Referring to FIGS. 5 and 6, a part of the p-doped GaN layers 21 and 23, for example, the central part thereof, may be removed. Partial removal of the p-doped GaN layers 21 and 23 can be accomplished by a process such as etching. In this regard, the anode 17 can be formed to have a ring shape in the remaining portion after partial removal, and the cathode 15 can be formed with a larger area to cover the entire area occupied by the anode 17.

Meanwhile, referring to FIG. 6, a rough structure 19 may be formed on a part of the n-doped GaN layer 11, for example, at least a part of the bottom surface thereof.

FIG. 7 illustrates a GaN-based radiation detector according to another embodiment of the present invention. Referring to FIG. 7, the same n-doped GaN layer 11 as described above is provided, and an additional n-doped GaN layer 31 is formed on the bottom surface of the n-doped GaN layer 11.

As described above, the n-doped GaN layer 11 is doped with an n-type doping concentration of 3×10¹⁶/cm3 or less, has an electron mobility of 700 cm²/(V·s) or more, and has a thickness of 300 um or more. The additionally formed n-doped GaN layer 31 has a thickness of 5 um or less, and is doped with an n-type doping concentration of 5×10¹⁷/cm³ or more.

Metal contacts 15 and 17 are formed on the lower surface of the n-doped GaN layer 31 and the upper surface of the n-doped GaN layer 11, respectively, and thereby a cathode and an anode can be formed.

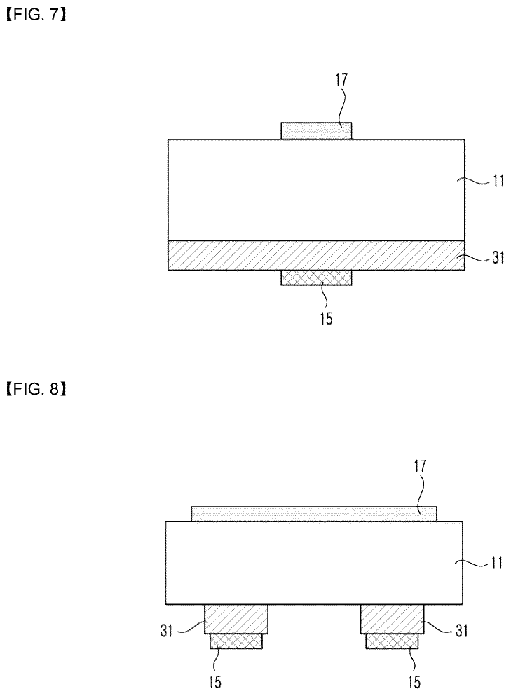

FIGS. 8 and 9 illustrate modified examples of the GaN-based radiation detector of FIG. 7. The same reference numerals are used for the same parts, and repeated descriptions are omitted. Referring to FIGS. 8 and 9, a part of the n-doped GaN layer 31, for example, a central part thereof, can be removed. The removal of a part of the n-doped GaN layer 31 can be performed by a process such as etching. At this time, the cathode 15 can be formed to have a ring shape in the remaining part after the partial removal, and the anode 17 can be formed with a larger area to cover the entire area occupied by the cathode 15.

Meanwhile, referring to FIG. 9, a rough structure 19 may be formed on a portion of the n-doped GaN layer 31, for example, on at least a portion of the bottom surface exposed by removing a portion of the n-doped GaN layer 11. Here, the bottom surface of the n-doped GaN layer 11 may be a nitrogen surface where nitrogen atoms are mainly exposed.

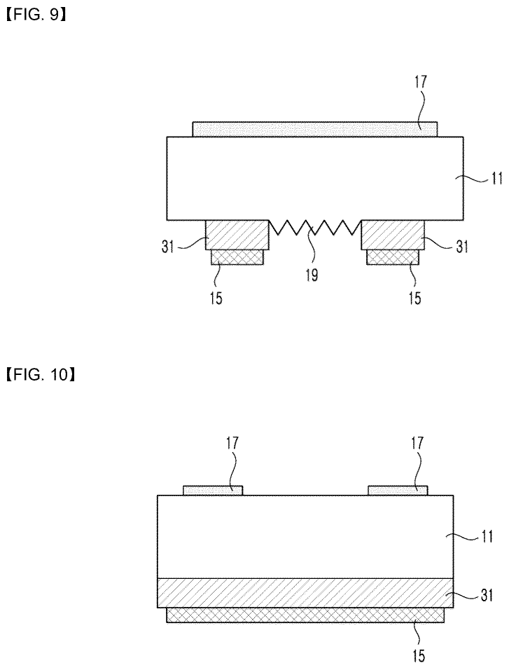

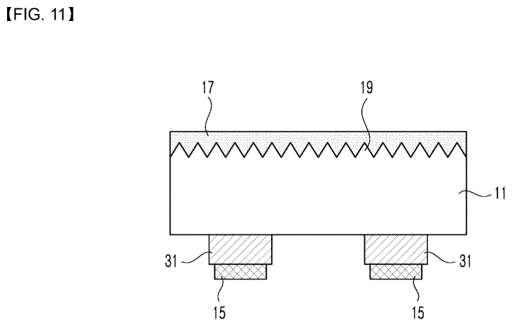

FIGS. 10 and 11 illustrate another modified example of the GaN-based radiation detector of FIG. 7. Referring to FIG. 10, the anode 17 may be formed to have a ring shape, and the cathode 15 may be formed to have a larger area corresponding to the entire area occupied by the anode 17.

Meanwhile, referring to FIG. 11, a portion of the n-doped GaN layer 31, for example, the central portion thereof, may be removed, and the cathode 15 may be formed to have a ring shape. A rough structure 19 can be formed on the upper surface of the n-doped GaN layer 11, which is a GaN substrate, and the anode 17 can be formed on the rough structure 19.

Although the embodiments of the present invention have been described above, the scope of the present invention is not limited thereto, and various modifications and improvements made by those skilled in the art using the basic concept of the present invention defined in the following claims also fall within the scope of the present invention.

1. A GaN-based radiation detector comprising:
an n-doped GaN layer having an electron mobility of 700 cm²/(V·s) or more and a thickness of 300 μm or more and doped with an n-type doping concentration of 3×10¹⁶/cm³ or less;
a p-doped GaN layer formed on one surface of the n-doped GaN layer and having a thickness of 3 μm or less and doped with a p-type doping concentration of 5×10¹⁸/cm³ or more as a p-type;
a first metal contact formed on the other surface of the n-doped GaN layer; and
a second metal contact formed on one surface of the p-doped GaN layer.

2. A GaN-based radiation detector comprising:
an n-doped GaN layer having an electron mobility of 700 cm²/(V·s) or more and a thickness of 300 μm or more and doped with an n-type doping concentration of 3×10¹⁶/cm³ or less;
a first p-doped GaN layer formed on one surface of the n-doped GaN layer and doped with a first p-doping concentration of 5×10¹⁸/cm³ or more;
a second p-doped GaN layer formed on one surface of the first p-doped GaN layer and doped with a second doping concentration of 5×10¹⁹/cm³ or more that is greater than the first p-doping concentration;
a first metal contact formed on the other surface of the n-doped GaN layer; and
a second metal contact formed on one surface of the second p-doped GaN layer.

3. A GaN-based radiation detector comprising:
an n-doped GaN layer having an electron mobility of 700 cm²/(V·s) or more and a thickness of 300 μm or more and doped with an n-type doping concentration of 3×10¹⁶/cm³ or less;
a plurality of p-doped GaN layers formed on one surface of the n-doped GaN layer and sequentially doped with different p-doping concentrations in a range of 5×10¹⁸/cm³ to 5×10²⁰/cm³ and having a thickness of 1 μm or less;
a first metal contact formed on the other surface of the n-doped GaN layer; and
a second metal contact formed on one surface of the plurality of p-doped GaN layers.

4. The GaN-based radiation detector of claim 1, wherein a part of the p-doped GaN layer is able to be removed.

5. The GaN-based radiation detector of claim 1, wherein at least a portion of one surface of the n-doped GaN layer has a rough structure.

6. The GaN-based radiation detector of claim 1, wherein a defect concentration of the n-doped GaN layer is 5×10⁶/cm² or less.

7. A GaN-based radiation detector comprising:
a first n-doped GaN layer having an electron mobility of 700 cm2/(V·s) or more and a thickness of 300 μm or more and doped with an n-type doping concentration of 3×10¹⁶/cm³ or less;
a second n-doped GaN layer formed on one surface of the first n-doped GaN layer and having a thickness of 5 μm or less and doped with an n-type doping concentration of 5×10¹⁷/cm³ or more;
a first metal contact formed on the other surface of the first n-doped GaN layer; and
a second metal contact formed on one surface of the second n-doped GaN layer.

8. The GaN-based radiation detector of claim 7, wherein a part of the second n-doped GaN layer is able to be removed.

9. The GaN-based radiation detector of claim 1, wherein at least a portion of a nitrogen surface of the n-doped GaN layer is formed to have a rough structure.

10. The GaN-based radiation detector of claim 2, wherein at least a portion of a nitrogen surface of the n-doped GaN layer is formed to have a rough structure.

11. The GaN-based radiation detector of claim 3, wherein at least a portion of a nitrogen surface of the n-doped GaN layer is formed to have a rough structure.

12. The GaN-based radiation detector of claim 2, wherein a part of the p-doped GaN layer is able to be removed.

13. The GaN-based radiation detector of claim 3, wherein a part of the p-doped GaN layer is able to be removed.

14. The GaN-based radiation detector of claim 2, wherein at least a portion of one surface of the n-doped GaN layer has a rough structure.

15. The GaN-based radiation detector of claim 3, wherein at least a portion of one surface of the n-doped GaN layer has a rough structure.

16. The GaN-based radiation detector of claim 2, wherein a defect concentration of the n-doped GaN layer is 5×10⁶/cm² or less.

17. The GaN-based radiation detector of claim 3, wherein a defect concentration of the n-doped GaN layer is 5×10⁶/cm² or less.
